(19) United States
(12) Patent Application Publication
(10) Pub. No.: US 2026/0271586 A1
(43) Pub. Date: Sep. 10, 2026

(54) DISPLAY PANEL AND METHOD FOR MANUFACTURING DISPLAY PANEL

(71) Applicants: Mianyang BOE Optoelectronics Technology Co., Ltd., Mianyang, Sichuan (CN); BOE Technology Group Co., Ltd., Beijing (CN)

(72) Inventors: Bo XIAO, Beijing (CN); Yaohong TAN, Beijing (CN); Zhen LIU, Beijing (CN); Feng BAI, Beijing (CN); Wen SUN, Beijing (CN); Zhengping XIONG, Beijing (CN); Fukun SUN, Beijing (CN)

(73) Assignees: Mianyang BOE Optoelectronics Technology Co., Ltd., Mianyang, Sichuan (CN); BOE Technology Group Co., Ltd., Beijing (CN)

(21) Appl. No.: 18/993,589

(22) PCT Filed: Aug. 21, 2024
(86) PCT No.: PCT/CN2024/113550

§ 371 Date: Jan. 13, 2025

(30) Foreign Application Priority Data
Sep. 27, 2023 (CN) 202311267402.3

(51) Int. Cl. H10K 59/80; H10K 50/19; H10K 59/12; H10K 59/40

(52) U.S. Cl. CPC H10K 59/873; H10K 50/19; H10K 59/1201; H10K 59/40

(57) ABSTRACT

Disclosed is a display panel, including: a substrate, having a display region and an edge region outside the display region; a first protruding structure, disposed in the edge region on the substrate and including a plurality of film layers which are stacked, wherein the plurality of film layers include at least one metal layer; a light-emitting, disposed on a side of the first protruding structure away from the substrate, disposed in the display region and the edge region, and disconnected on the first protruding structure; and a first encapsulation layer, disposed on a side of the light-emitting layer away from the substrate.

### CROSS-REFERENCE TO RELATED APPLICATIONS

The present disclosure is a U.S. national phase application based on PCT/CN2024/113550, filed on Aug. 21, 2024, which claims priority to Chinese Patent Application No. 202311267402.3, filed on Sep. 27, 2023, and entitled “DISPLAY PANEL AND METHOD FOR MANUFACTURING DISPLAY PANEL”, the disclosure of each are incorporated herein by reference in its entirety.

### TECHNICAL FIELD

The present disclosure relates to the field of display technologies, and in particular, relates to a display panel and a method for manufacturing the display panel.

### BACKGROUND

A display panel is a device that enables a display function.

At present, a display panel includes a substrate, and a protruding structure, a light-emitting layer, and an encapsulation layer that are sequentially arranged on the substrate. The light-emitting layer can emit light under driving to realize a display function. The protruding structure is disposed at an edge of the substrate and tops up the light-emitting layer disposed at the edge, such that the light-emitting layer forms a concave-convex shape at the edge, thereby preventing moisture in the external environment from entering the display panel.

### SUMMARY

Embodiments of the present disclosure provide a display panel and a method for manufacturing the display panel. The technical solutions are as follows.

According to one aspect of the embodiments of the present disclosure, a display panel is provided, including:
a substrate, having a display region and an edge region disposed outside the display region;
a first protruding structure, disposed in the edge region on the substrate and including a plurality of film layers which are stacked, wherein the plurality of film layers include at least one metal layer;
a light-emitting layer, disposed on a side of the first protruding structure away from the substrate, disposed in the display region and the edge region, and disconnected on the first protruding structure; and
a first encapsulation layer, disposed on a side of the light-emitting layer away from the substrate.

In some embodiments, the substrate has an opening hole, the edge region includes at least one of an opening-hole edge region and a substrate edge region, wherein the opening-hole edge region is a region including an edge of the opening hole, and the substrate edge region is a region including an outer edge of the substrate.

In some embodiments, the first protruding structure further includes at least one of an organic layer and an inorganic layer.

In some embodiments, the number of first protruding structures is at least two, film layers in the at least two first protruding structures including at least one of three structures, wherein the three structures include:
a metallic layer and an inorganic layer;
a metallic layer and an organic layer; and
a metallic layer, an organic layer, and an inorganic layer.

In some embodiments, the display panel further includes at least one of a metal shielding layer, a first gate metal pattern, a second gate metal pattern, a third gate metal pattern, a first source-drain metal pattern, a second source-drain metal pattern, and a third source-drain metal pattern disposed on the substrate;
wherein the metal layer in the first protruding structure includes at least one of a first metal layer, a second metal layer, a third metal layer, a fourth metal layer, a fifth metal layer, a sixth metal layer, and a seventh metal layer, wherein the first metal layer is of the same layer structure as the metal shielding layer, the second metal layer is of the same layer structure as the first gate metal pattern, the third metal layer is of the same layer structure as the second gate metal pattern, the fourth metal layer is of the same layer structure as the third gate metal pattern, the fifth metal layer is of the same layer structure as the first source-drain metal pattern, the sixth metal layer is of the same layer structure as the second source-drain metal pattern, and the seventh metal layer is of the same layer structure as the third source-drain metal pattern.

In some embodiments, the number of first protruding structures is at least two, the at least two first protruding structures including two adjacent first protruding structures;
wherein the display panel further includes a filling structure, wherein the filling structure is disposed between and in contact with the two adjacent first protruding structures, and the filling structure includes an organic material layer.

In some embodiments, the display panel further includes at least one second protruding structure, wherein the second protruding structure is disposed in the edge region and includes at least one organic layer;
wherein the light-emitting layer is disposed on the substrate formed with the second protruding structure and is disconnected on the second protruding structure.

In some embodiments, the display panel further includes at least one third protruding structure, wherein the third protruding structure is disposed in the edge region on the substrate and is formed by a metal layer, a recessed structure is disposed in at least one of a first side surface of the third protruding structure close to the display region and a second side surface of the third protruding structure away from the display region;
wherein the light-emitting layer is disposed on the substrate formed with the third protruding structure and is disconnected at the recessed structure of the third protruding structure.

In some embodiments, the at least one metal layer includes a target metal layer, wherein an edge of the target metal layer protrudes, in a direction parallel to the substrate, from the first protruding structure.

In some embodiments, the display panel further includes a crack blocking structure, wherein the crack blocking structure is disposed in the edge region and on a side of the first protruding structure away from the display region.

In some embodiments, the display panel further includes an edge organic material layer, the edge organic material layer covering the crack blocking structure.

In some embodiments, the first protruding structure is enclosed by a top surface, a bottom surface, and a side surface, the top surface being disposed on a side of the bottom surface away from the substrate; and
the light-emitting layer includes a first opening, the first opening being disposed on the top surface.

In some embodiments, the display panel further includes a second encapsulation layer;
wherein the second encapsulation layer is disposed on a side of the light-emitting layer away from the substrate and has an encapsulation layer opening, wherein an orthographic projection of the encapsulation layer opening on the substrate overlaps an orthographic projection of the first opening on the substrate; and
the first encapsulation layer is disposed on a side of the second encapsulation layer away from the substrate and covers the encapsulation layer opening.

In some embodiments, the display panel further includes a second encapsulation layer, wherein the second encapsulation layer is disposed between the first encapsulation layer and the light-emitting layer and covers the first opening in the light-emitting layer.

In some embodiments, the light-emitting layer includes a plurality of sub-light-emitting layers disposed in the display region;
the display panel includes a plurality of light-emitting units, wherein each of the light-emitting units includes an electrode and the sub-light-emitting layers, the electrodes being in contact with the sub-light-emitting layers; and
the second encapsulation layer is disposed on a side of the plurality of light-emitting units away from the substrate to encapsulate the plurality of light-emitting units.

In some embodiments, the display panel further includes a touch structure, wherein the touch structure is disposed on the side of the second encapsulation layer away from the substrate; and
the first encapsulation layer is disposed on a side of the touch structure away from the substrate to encapsulate the touch structure.

In some embodiments, the number of the first protruding structures is at least two; and the light-emitting layer includes a second opening, wherein an orthographic projection of the second opening on the substrate is disposed between orthographic projections of two adjacent first protruding structures in the at least two first protruding structures on the substrate.

In some embodiments, the first protruding structure is enclosed by a top surface, a bottom surface, and a side surface, wherein the top surface is disposed on a side of the bottom surface away from the substrate, and the side surface includes a first side surface close to the display region, and a second side surface away from the display region; and
the light-emitting layer is disposed on the first side surface, and is not disposed on the top surface and the second side surface.

In some embodiments, the light-emitting layer includes an electroluminescent material layer and a functional layer, wherein the functional layer includes at least one of a hole injection layer, a hole transporting layer, an electron transporting layer, an electron injection layer, and a cathode layer.

According to another aspect provided by the embodiments of the present disclosure, a method for manufacturing a display panel is provided, including:
acquiring a substrate, wherein the substrate has a display region and an edge region disposed outside the display region;
forming a first protruding structure, a light-emitting layer, and a first encapsulation layer on the substrate, wherein the first protruding structure is disposed in the edge region on the substrate and includes a plurality of film layers which are stacked, the plurality of film layers including at least one metal layer; the light-emitting layer is disposed on the substrate formed with the first protruding structure, disposed in the display region and the edge region, and disconnected on the first protruding structure; and the first encapsulation layer is disposed on a side of the light-emitting layer away from the substrate.

In some embodiments, forming the first protruding structure, the light-emitting layer, and the first encapsulation layer on the substrate includes:
forming the first protruding structure on the substrate;
forming the light-emitting layer on the substrate formed with the first protruding structure;
forming a second encapsulation layer on the substrate formed with the light-emitting layer;
forming a target opening in the second encapsulation layer and the light-emitting layer by an etching process to disconnect the light-emitting layer on the first protruding structure, wherein an orthographic projection of the target opening on the substrate overlaps an orthographic projection of the first protruding structure on the substrate; and
forming the first encapsulation layer on a side of the second encapsulation layer away from the substrate, wherein the first encapsulation layer covers the target opening.

According to another aspect of the embodiments of the present disclosure, a display device is provided. The display device includes a power supply assembly and the display panel as described above, wherein the power supply assembly is electrically connected to the display panel.

The beneficial effects of the technical solutions provided by the embodiments of the present disclosure include at least:

A display panel is provided, including a substrate, a first protruding structure, a light-emitting layer, and an encapsulation layer, wherein the first protruding structure is disposed in an edge region outside a display region, the light-emitting layer is disposed on the first protruding structure and disconnected on the protruding structure. In this way, the moisture in the external environment can be prevented from intruding into the display region of the display panel through the light-emitting layer, such that the risk of the display panel being damaged is reduced by the moisture in the external environment erosion, thereby solving the problem that the poor stability of the display panel caused by the weakness of the display panel's ability to block the moisture in the external environment in the related art, and then achieving the effect of increasing the lifespan of the display panel.

In addition, in a manufacturing process of the light-emitting layer and the second encapsulation layer in the display panel with this structure, a metal mask plate is not needed, such that the number of metal mask plates used in the manufacturing process can be reduced, and the effect of reducing the manufacturing cost of the display panel is realized.

In addition, the light-emitting layer disconnected on the first protruding structure also reduces the problem of easy separation of a top of the first protruding structure from an upper film layer in the edge region.

### BRIEF DESCRIPTION OF DRAWINGS

For clearer descriptions of the technical solutions in the embodiments of the present disclosure, the following briefly introduces the accompanying drawings required for describing the embodiments. Apparently, the accompanying drawings in the following description illustrate merely some embodiments of the present disclosure, and persons of ordinary skill in the art may still derive other drawings from these accompanying drawings without creative efforts.

FIG. 1 is a schematic top view of a display panel;

FIG. 2 is a schematic cross-sectional view of the display panel shown in FIG. 1;

FIG. 3 is a schematic top view of a display panel according to some embodiments of the present disclosure;

FIG. 4 is a schematic cross-sectional view of the display panel shown in FIG. 3;

FIG. 5 is a schematic diagram of a film structure of the light-emitting layer shown in FIG. 4;

FIG. 6 is a schematic top view of another display panel according to some embodiments of the present disclosure;

FIG. 7 is a schematic cross-sectional view of the display panel shown in FIG. 6;

FIG. 8 is another schematic cross-sectional view of the display panel shown in FIG. 6;

FIG. 9 is another schematic cross-sectional view of the display panel shown in FIG. 6 according to some embodiments of the present disclosure;

FIG. 10 is another schematic cross-sectional view of FIG. 6 according to some embodiments of the present disclosure;

FIG. 11 is another schematic cross-sectional view of the display panel shown in FIG. 6;

FIG. 12 is another schematic cross-sectional view of the display panel shown in FIG. 6;

FIG. 13 is another schematic cross-sectional view of the display panel shown in FIG. 6;

FIG. 14 is another schematic cross-sectional view of the display panel shown in FIG. 6;

FIG. 15 is an enlarged schematic diagram of a partial region in the display panel shown in FIG. 6;

FIG. 16 is another schematic cross-sectional view of the display panel shown in FIG. 6;

FIG. 17 is another schematic cross-sectional view of the display panel shown in FIG. 6;

FIG. 18 is another schematic cross-sectional view of the display panel shown in FIG. 6;

FIG. 19 is a flowchart of a method for manufacturing a display panel according to some embodiments of the present disclosure; and

FIG. 20 is a flowchart of another method for manufacturing a display panel according to some embodiments of the present disclosure.

Specific embodiments of the present disclosure have been illustrated by means of the above-described accompanying drawings, which are described in more detail hereinafter. These accompanying drawings and textual descriptions are not intended to limit the scope of the present disclosure idea in any way, but rather to illustrate the concepts of the present disclosure for those skilled in the art by reference to particular embodiments.

### DETAILED DESCRIPTION

In order to make the objectives, technical solutions, and advantages of the present disclosure clearer, the following further describes the embodiments of the present disclosure in detail with reference to the accompanying drawings.

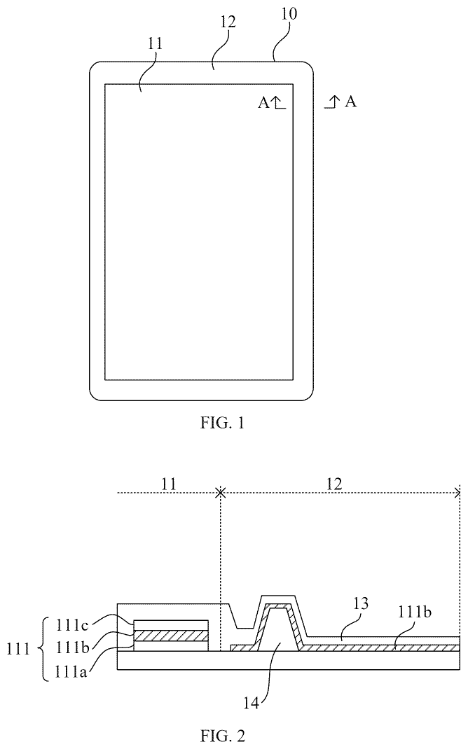

FIG. 1 is a schematic top view of a display panel, and FIG. 2 is a schematic cross-sectional view of the display panel shown in FIG. 1 (the cross-sectional position is A-A). Referring to FIG. 1 and FIG. 2, the display panel 10 includes a display region 11, and an edge region 12 disposed outside the display region 11 The display region 11 includes a plurality of light-emitting units 111, the light-emitting units 111 can be configured to emit light of various colors to achieve an image display function. The light-emitting unit 111 may include an anode 111a, a light-emitting layer 111b, and a cathode 111c, and the anode 111a and the cathode 111c may drive the light-emitting layer 111b to emit light.

An encapsulation layer 13 is arranged on the light-emitting unit 111, and the encapsulation layer 13 may cover the light-emitting unit 111 to encapsulate the light-emitting unit 111, such that the light-emitting unit 111 is protected and is prevented from being damaged by erosion of the moisture in the external environment.

In the edge region 12 near an edge of the display panel 10, a blocking dam 14 is provided, and the light-emitting unit 111 is not provided in the edge region 12, but in some processes of manufacturing the display panel, the light-emitting layer 111b is formed in the edge region 12 and covers the blocking dam 14. The blocking dam 14 can be configured to block some film layers in the display region 11 from spreading towards the edge region 12 during formation. In addition, the blocking dam 14 may also be configured to block the moisture in the external environment from entering the display region 11, thereby reducing the risk of the light-emitting unit 111 in the display region 11 being damaged by the moisture in the external environment.

However, it is still possible for the moisture in the above-described display panel to intrude into the display region 11 through the light-emitting layer in the edge region 12 and erode the light-emitting unit 111 in the display region 11, such that the lifespan of the display panel is short.

The embodiments of the present disclosure provide a display panel that can solve some of the above problems in the related art.

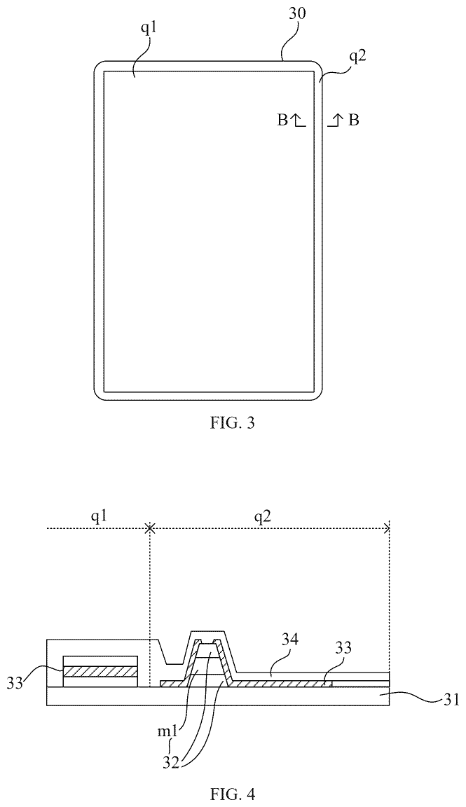

FIG. 3 is a schematic top view of a display panel according to some embodiments of the present disclosure, and FIG. 4 is a schematic cross-sectional view of the display panel shown in FIG. 3 (FIG. 4 is a schematic cross-sectional view of FIG. 3 at B-B). Referring to FIG. 3 and FIG. 4, the display panel 30 includes:
a substrate 31, having a display region q1 and an edge region q2 disposed outside the display region q1;
a first protruding structure 32, disposed in the edge region q2 on the substrate 31 and including a plurality of film layers which are stacked, wherein the plurality of film layers includes at least one metal layer ml;
a light-emitting layer 33, disposed on a side of the first protruding structure 32 away from the substrate 31, disposed in the display region q1 and the edge region q2 on the substrate 31, and disconnected on the first protruding structure 32, wherein, as can be seen from FIG. 4, the light-emitting layer 33 is disconnected at s on the first protruding structure 32, which in turn can block the moisture in the external environment (water and various gases) from intruding into the display region q1 of the display panel through the light-emitting layer 33; and
a first encapsulation layer 34, disposed on a side of the light-emitting layer 33 away from the substrate 31, wherein the encapsulation layer 34 may be configured to encapsulate some structures in the display region q1 (such as the light-emitting layer 33 disposed in the display region q1) to prevent the structures from being affected by the external environment.

It is to be noted that the light-emitting layer 33 being disconnected on the first protruding structure 32 may mean that the light-emitting layer 33 is separated by the first protruding structure 32 into two portions disposed on both sides of the first protruding structure 32. The two portions are spaced apart on the first protruding structure 32, and the spacing may separate the light-emitting layer 33 into one portion close to the display region q1 and the other portion away from the display region q1 (FIG. 4 shows such a structure). Alternatively, the light-emitting layer 33 being disconnected on the first protruding structure 32 may mean that the light-emitting layer 33 is cut off on the first protruding structure 32, i.e., an edge of the light-emitting layer 33 may cover the first protruding structure 32 and no longer extend in a direction away from the display region q1.

It should be noted that the portion of the light-emitting layer 33 disposed in the display region q1 and the portion of the light-emitting layer 33 disposed in the edge region q2 in FIG. 3 are disconnected and are shown as a schematic structure for ease of illustration, but do not limit the actual structure. That is, the portion of the light-emitting layer 33 disposed in the display region q1 and the portion of the light-emitting layer 33 disposed in the edge region q2 may be connected to each other.

In summary, the embodiments of the present disclosure provide a display panel, including a substrate, a first protruding structure, a light-emitting layer, and an encapsulation layer. The first protruding structure is disposed in an edge region outside a display region, the light-emitting layer is disposed on the first protruding structure, and the light-emitting layer is disconnected on the protruding structure. In this way, the moisture in the external environment can be prevented from intruding into the display region of the display panel through the light-emitting layer, such that the risk of the display panel being damaged is reduced by the moisture in the external environment, thereby solving the problem that the poor stability of the display panel caused by the weakness of the display panel's ability to block the moisture in the external environment in the related art, and then achieving the effect of increasing the lifespan of the display panel.

In addition, in the manufacturing process of the light-emitting layer in the display panel with this structure, a metal mask plate is not needed, the number of metal mask plates used in the manufacturing process can be reduced, and the effect of reducing the manufacturing cost of the display panel is realized.

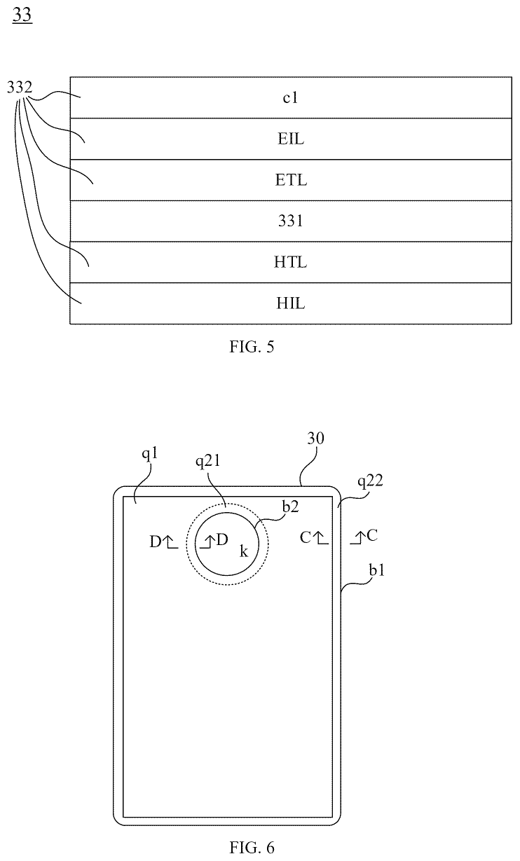

FIG. 5 is a schematic diagram of a film structure of the light-emitting layer shown in FIG. 4. Referring to FIG. 4 and FIG. 5, the light-emitting layer 33 includes an electroluminescent material layer 331 and a functional layer 332. The functional layer 332 includes at least one of a hole injection layer (HIL), a hole transporting layer (HTL), an electron transporting layer (ETL), an electron injection layer (EIL), and a cathode layer c1.

The portion of the electroluminescent material layer 331 and the functional layer 332 disposed in the light-emitting layer 33 disposed in the display region q1 can cooperate to achieve the function of emitting light, and the portion of the electroluminescent material layer 331 and the functional layer 332 in the light-emitting layer 33 disposed in the edge region q2 can be a film layer formed in the edge region q2 due to a process. The portion of the film layer disposed in the edge region q2 cannot be configured to achieve the function of emitting light. In addition, the light-emitting layer 33 may also include two cathode protect layers (CPL) which are stacked.

In the display region q1 of the display panel, a light-emitting unit may be defined by the light-emitting layer 33 disposed in the display region q1 together with some other structures (e.g., an anode and a driving circuit, etc.), and a plurality of light-emitting units in the display region q1 may be provided to emit light of different colors. Exemplarily, the display region may be provided with one or more of a red light-emitting unit to emit red light, a green light-emitting unit to emit green light, a blue light-emitting unit to emit blue light, and a white light-emitting unit to emit white light. Each of the light-emitting units may be provided with a different light-emitting layer. In the case that the plurality of light-emitting units are provided in the display region, a plurality of light-emitting layers of the plurality of light-emitting units may correspondingly be provided in the edge region q2. The plurality of light-emitting layers may be stacked in the edge region q2, and the plurality of stacked light-emitting layers in the edge region q2 may be partially or wholly disconnected on the first protruding structure in the display panel provided by the embodiments of the present disclosure.

Alternatively, in the display panel provided by the embodiments of the present disclosure, the light-emitting unit may include an organic light-emitting diode, and a structure of a light-emitting layer in the organic light-emitting diode may be shown in FIG. 5. Alternatively, in the display panel provided by the embodiments of the present disclosure, the light-emitting unit may include a tandem organic light-emitting diode (Tandem OLED), and the Tandem OLED is a type of OLED device formed by stacking a plurality of conventional OLED devices in series with each other through a connection layer. Correspondingly, the structure of the light-emitting layer is different.

Referring to FIG. 6, FIG. 6 is a schematic top view of another display panel according to some embodiments of the present disclosure. A substrate in the display panel includes a plurality of edges, such as an outer edge b1 of the substrate (the outer edge b1 is an outermost edge of the substrate that defines the shape of the substrate). The substrate also has an edge b2 of an opening hole k when the display panel includes the opening hole k. The edge region involved in the embodiments of the present disclosure may include at least one of an opening-hole edge region q21 and a substrate edge region q22. The opening-hole edge region q21 is a region including the edge b2 of the opening hole k, and the substrate edge region q22 is a region including the outer edge b1 of the substrate. That is, the above structure provided in the embodiments of the present disclosure can be applied to at least one edge of the plurality of edges in the display panel. The opening hole k may be a light-transmitting opening hole, and when the display panel is applied in a display device, the back side of the display panel may be provided with some sensors (such as an image sensor, an infrared sensor, etc.), and these sensors can collect some information in the front side of the display panel through the opening hole k.

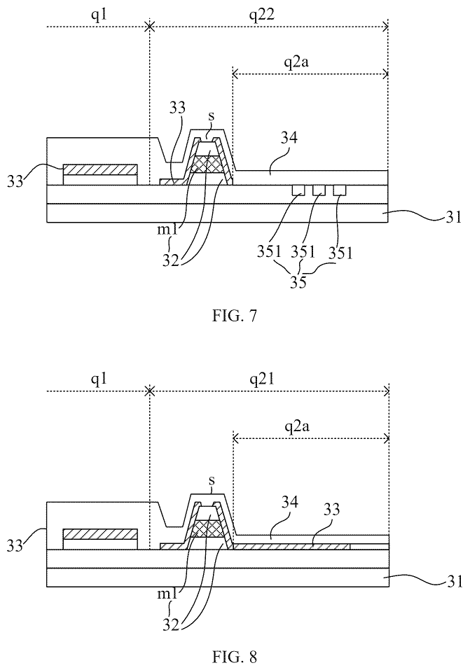

FIG. 7 is a schematic cross-sectional view of the display panel shown in FIG. 6 (the cross-sectional position may be at C-C). Referring to FIG. 6 and FIG. 7, in some embodiments, a first protruding structure 32 may be arranged in the substrate edge region q22 of the substrate 31 of the display panel, and the light-emitting layer 33 covering the first protruding structure 32 may be disconnected on the first protruding structure 32, such that the moisture in the external environment may be prevented from intruding into the interior of the display panel through the display panel edge, thereby achieving the effect of increasing the lifespan of the display panel.

In some embodiments, the display panel further includes a crack blocking structure 35. The crack blocking structure 35 is disposed in the substrate edge region q22 and on the side of the first protruding structure 32 away from the display region q1. The crack blocking structure 35 may include one or more crack blocking blocks 351, and the plurality of crack blocking blocks 351 may be configured to block the cracks of each film layer in the substrate edge region q22 during the cutting of the display panel in the substrate edge region q22, such that the cracks are prevented from extending to the display region q1, thereby improving the manufacturing yield of the display panel. In addition, the crack blocking structure 35 may also have a certain moisture blocking capability to prevent the moisture in the external environment from entering the display region q1 of the display panel. The crack blocking structure 35 may be of the same layer structure as one or more planarization layers in the display panel. It is to be noted that the embodiments of the present disclosure relate to “A” and “B” being of the same layer structure, which may mean that “A” and “B” are structures of the same material formed by the one-time patterning process. In addition, the patterning process involved in the embodiments of the present disclosure may include processes such as forming a photoresist, exposing, developing, etching, and stripping the photoresist.

In some embodiments, in the substrate edge region q22, the light-emitting layer 33 may not be arranged in a region q2a disposed on the side of the first protruding structure 32 away from the display region q1, which can also prevent the moisture in the external environment from intruding into the display region of the display panel through the light-emitting layer, and then improve the blocking ability of the display panel for the moisture in the external environment. The light-emitting layer 33 may be removed by a patterning process or a laser process. The light-emitting layer disposed in a region of the first protruding structure 32 on a side of the first protruding structure 32 away from the display region q1 while removing the light-emitting layer on the top of the first protruding structure 32 by the patterning process. FIG. 7 shows a structure in which the light-emitting layer 33 is not arranged in the region q2a, and the light-emitting layer 33 may also be arranged in the region q2a, which is not limited in the embodiments of the present disclosure.

FIG. 8 is another schematic cross-sectional view of the display panel shown in FIG. 6 (the cross-sectional position may be at D-D). Referring to FIG. 6 and FIG. 8, in other embodiments, the opening-hole edge region q21 of the display panel may be provided with the first protruding structure 32, and the light-emitting layer 33 covering the first protruding structure 32 may be disconnected on the first protruding structure 32, such that the moisture in the external environment is prevented from intruding into the display region q1 of the display panel through the light-emitting layer 33 at the edge of the opening hole of the substrate of the display panel, thereby increasing the lifespan of the display panel. FIG. 8 shows a structure in which the light-emitting layer 33 is arranged in the region q2a on the side of the first protruding structure 32 away from the display region q1, but the light-emitting layer 33 may not be arranged in the region q2a. In addition, the structure shown in FIG. 8 may also include the crack blocking structure 35 shown in FIG. 7, which is not limited in the embodiments of the present disclosure.

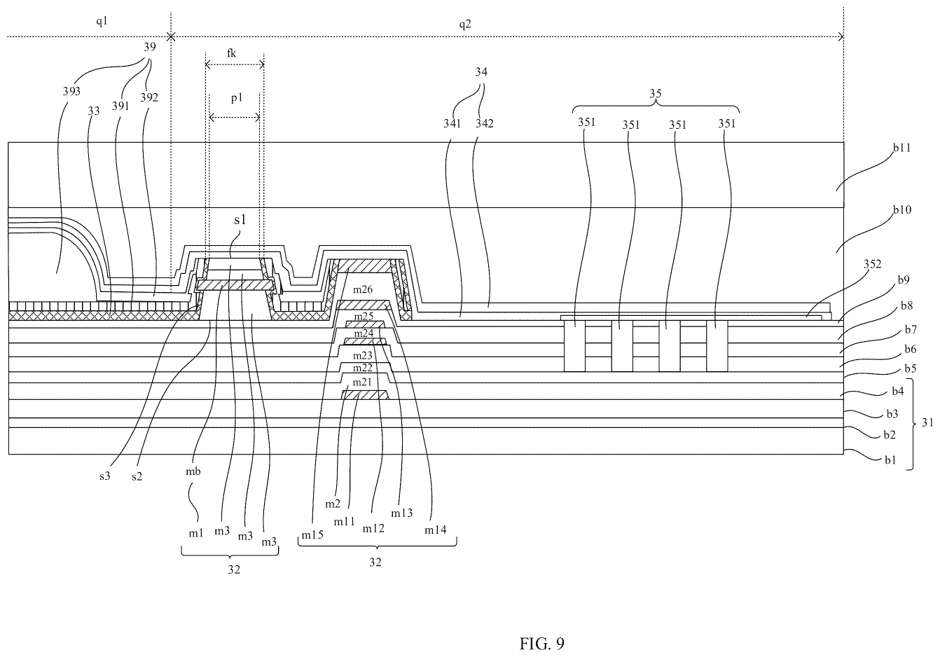

In some embodiments, referring to FIG. 9, which is another schematic cross-sectional view of the display panel shown in FIG. 6 (the cross-sectional position may be at C-C or D-D). The display panel further includes an edge organic material layer 352, and the edge organic material layer 352 covers the crack blocking structure 35. The edge organic material layer 352 may have the ability to block cracks, and may cooperate with the crack blocking structure 35 to further improve the crack blocking ability of the display panel and reduce the cracks at the edges from spreading into the display region of the display panel, thereby enhancing the manufacturing yield of the display panel. The edge organic material layer 352 may be of the same layer structure as a pixel defining layer constituted by the organic material in the display panel.

In some embodiments, a plurality of film layers stacked in the first protruding structure may include some other film layers in addition to the metal layer. For example, at least one of the organic layer and the inorganic layer may also be included in the first protruding structure. Also, the number of the first protruding structures 32 may be one or more. When the number of the first protruding structures 32 is at least two, the film layers included in the at least two first protruding structures 32 include at least one of three structures, and the three structures include:
1) a metal layer and an inorganic layer;
2) a metal layer and an organic layer;
3) a metal layer, an organic, and an inorganic layer.

FIG. 9 shows a structure in which the number of the first protruding structures 32 is two. One first protruding structure 32 includes a metal layer m1 and an organic layer m3, and the other first protruding structure 32 includes the metal layer m1 and an inorganic layer m2, which is not limited in the embodiments of the present disclosure. The metal layer m1, the inorganic layer m2, and the organic layer m3 included in the first protruding structure 32 may all be one or more layers, and are stacked to form the first protruding structure 32 on the substrate.

Also, the film layers included in the first protruding structure 32 may be film layers formed in the one-time patterning process alone or film layers formed simultaneously in the process of forming other film layers. Exemplarily, the metal layer m1 may be a metal layer formed in the one-time patterning process during forming the other metal layers of the display panel, the inorganic layer m2 may be an inorganic layer formed in the one-time patterning process during forming the other inorganic layers of the display panel, and the organic layer m3 may be an organic layer formed in the one-time patterning process during forming the other organic layers of the display panel.

As the metal layer has the characteristics of structural robustness and stability, the metal layer being provided in the first protruding structure 32 may increase the structural stability of the first protruding structure 32.

In some embodiments, the display panel may include at least one of the metal film layers, such as a metal shielding layer, a first gate metal pattern (gate1), a second gate metal pattern (gate2), a third gate metal pattern (gate3), a first source-drain metal pattern (SD1), a second source-drain metal pattern (SD2), and a third source-drain metal pattern (SD3) disposed on the substrate 31.

Exemplarily, a display panel provided by the embodiments of the present disclosure includes the first gate metal pattern (gate1), the second gate metal pattern (gate2), the third gate metal pattern (gate3), the first source-drain metal pattern (SD1), the second source-drain metal pattern (SD2), and the third source-drain metal pattern (SD3).

In another display panel, the first gate metal pattern (gate1), the second gate metal pattern (gate2), the third gate metal pattern (gate3), the first source-drain metal pattern (SD1), and the second source-drain metal pattern (SD2) are included.

In another display panel, the first gate metal pattern (gate1), the second gate metal pattern (gate2), the first source-drain metal pattern (SD1), and the second source-drain metal pattern (SD2) are included.

In another display panel, the first gate metal pattern (gate1), the second gate metal pattern (gate2), the first source-drain metal pattern (SD1), the second source-drain metal pattern (SD2), and the third source-drain metal pattern (SD3) are included.

The metal film layers may be configured to form various lines and structures in the display panel. Exemplarily, the metal shielding layer may be configured to mask some structures (e.g., active layers, etc.) in the display panel to avoid the structures being affected by factors such as light. Further, the display region q1 is provided with a pixel array for performing the display, the pixel array includes a plurality of pixel units arranged in an array, and each pixel unit includes structures such as the driving circuit and the light-emitting unit. The driving circuit may include structures such as a thin film transistor and a storage capacitor. The thin film transistor includes an active layer, a gate, a gate insulating layer, an interlayer insulating layer, and a source-drain electrode (including a source and a drain) sequentially disposed on the substrate. The storage capacitor includes a first plate and a second plate. For example, the first plate is arranged in the same layer as the gate, and the second pole plate is arranged between the gate insulating layer and the interlayer insulating layer.

The first gate metal pattern may include the first plate and a gate electrode of the thin film transistor, the second gate metal pattern may include the second plate, the third gate metal pattern may include the gate electrode of the thin film transistor, at least one of the first source-drain metal pattern and the second source-drain metal pattern may include a source-drain electrode of the thin film transistor, and the third source-drain metal pattern may also include the source-drain electrode of the thin film transistor.

The metal layer m1 in the first protruding structure 32 may include at least one of a first metal layer m11, a second metal layer m12, a third metal layer m13, a fourth metal layer m14, a fifth metal layer m15, a sixth metal layer (not shown in the drawings), and a seventh metal layer (not shown in the drawings).

The first metal layer m11 is of the same layer structure as the metal shielding layer, and thus the first metal layer m11 can be formed at the same time when the metal shielding layer is formed. The second metal layer m12 is of the same layer structure as the first gate metal pattern, and thus the second metal layer m12 can be formed at the same time when the first gate metal pattern is formed. The third metal layer m13 is of the same layer structure as the second gate metal pattern, and thus the third metal layer m13 can be formed at the same time when the second gate metal pattern is formed. The fourth metal layer m14 can be of the same layer structure as the third gate metal pattern, and thus the fourth metal layer m 14 can be formed at the same time when the third gate metal pattern is formed. The fifth metal layer m15 can be of the same layer structure as the first source-drain metal pattern, and thus the fifth metal layer m15 can be formed at the same time when the first source-drain metal pattern is formed. The sixth metal layer may be of the same layer structure as the second source-drain metal pattern, and thus the sixth metal layer may be formed at the same time when the second source-drain metal pattern is formed. The seventh metal layer is of the same layer structure as the third source-drain metal pattern, and thus the seventh metal layer can be formed at the same time when the third source-drain metal pattern is formed. In this way, the first protruding structure 32 can be formed without increasing the number of patterning processes.

In addition, the number of metal layers included in the first metal layer m11, and which metal layers are included, may be determined based on the height of the first protruding structure 32. For example, in the case that the height of the first protruding structure 32 is greater, the number of metal layers included in the first metal layer m11 may be greater, e.g., four or five metal layers may be included, and in the case that the height of the first protruding structure 32 is less, the number of metal layers included in the first metal layer m11 may be less, such as may include one or two metal layers. In addition, thicknesses of the metal film layers such as the metal shielding layer, the first gate metal pattern (gate1), the second gate metal pattern (gate2), the first source-drain metal pattern (SD1), and the second source-drain metal pattern (SD2) may not be equal. Thus, in the case that the height of the first protruding structure 32 needs to be reduced, the metal film layer with a less thickness among the metal film layers may be selected to form the first protruding structure 32, and in the case that the height of the first protruding structure 32 needs to be increased, the metal film layer with a greater thickness among the metal film layers may be selected to form the first protruding structure 32. In short, the effect of adjusting and controlling the height of the first protruding structure 32 may be achieved by selecting different metal layers and the number of metal layers.

In some embodiments, the first protruding structure 32 is enclosed by a top surface s1, a bottom surface s2, and a side surface s3, the top surface s1 being disposed on a side of the bottom surface s2 away from the substrate 31. The light-emitting layer 33 includes a first opening p1, the first opening p1 being disposed on the top surface s1. This first opening p1 enables a structure in which the light-emitting layer 33 is disconnected on the first protruding structure 32.

The first opening p1 may be formed in various ways. In some embodiments, the light-emitting layer 33 disposed on the top surface s1 of the first protruding structure may be etched by the patterning process to form the first opening p1. In addition, when the light-emitting layer 33 is etched by the patterning process, a film layer under the light-emitting layer 33 may be over-etched to ensure that the light-emitting layer 33 can be removed from the top surface s1 of the first protruding structure, and the over-etched thickness for the film layer under the light-emitting layer 33 may range from 3% to 8%.

In the embodiments of the present disclosure, the patterning process for the light-emitting layer in the edge region may also be referred to as an edge etch mask (EEM) process. The edge patterning process can be used to remove a portion of the light-emitting layer in the edge region to achieve enhanced blocking capability of the display panel against the moisture in the external environment.

In some embodiments, at least one metal layer includes a target metal layer mb, an edge of the target metal layer mb protruding, in a direction parallel to the substrate 31, from the first protruding structure 32. The target metal layer mb may protrude from the first protruding structure 32 at one end of the edge region q2 in a direction f1 toward the display region q1, or may protrude from the first protruding structure 32 at both ends in the direction f1. The target metal layer mb protruding from the first protruding structure 32 may form a blocking structure on a side of the first protruding structure 32 to further improve the blocking effect of the first protruding structure on the moisture in the external environment.

The target metal layer mb may be manufactured by an undercut process. In addition, the target metal layer mb may be disposed in the first protruding structure 32 in any one of the display panels provided in the embodiments of the present disclosure. In some exemplary embodiments, in the case that the first protruding structure 32 includes a plurality of metal layers, one or more of the metal layers may be the target metal layer mb with edges protruding from the first protruding structure. In the case that one first protruding structure 32 includes a plurality of target metal layers mb, the blocking effect of the first protruding structure 32 to the moisture in the external environment can be further improved.

In addition, the target metal layer mb may be any one of the first metal layer, the second metal layer, the third metal layer, the fourth metal layer, the fifth metal layer, the sixth metal layer, and the seventh metal layer involved in the above embodiments. Correspondingly, the target metal layer mb may be of the same layer structure as any one of the metal shielding layer, the first gate metal pattern, the second gate metal pattern, the third gate metal pattern, the first source-drain metal pattern, and the second source-drain metal pattern, such that the target metal layer mb can be formed without increasing the number of the patterning processes.

In the display panel provided in the embodiments of the present disclosure, the substrate 31 may include a plurality of film layers that are stacked. Exemplarily, the substrate 31 may include a first substrate layer b1, a second substrate layer b2, a third substrate layer b3, and a fourth substrate layer b4. The first substrate layer b1 and the third substrate layer b3 may be polyimide (PI) layers, and the second substrate layer b2 and the fourth substrate layer b4 may be inorganic buffer layers.

A first buffer layer b5, a first gate insulating layer b6, a second gate insulating layer b7, an intermediate dielectric layer b8, and a passivation layer b9 may also be arranged between the substrate 31 and the second encapsulation layer 39. Some of these film layers and some of the film layers in the substrate 31 may be used to form the first protruding structure.

Referring to FIG. 6 and FIG. 9, the first protruding structure 32 is enclosed by a top surface s1, a bottom surface s2, and a side surface s3, the top surface s1 being disposed on a side of the bottom surface s2 away from the substrate 31. The light-emitting layer 33 includes a first opening p1, the first opening pl being disposed on the top surface s1. This first opening p1 enables a structure in which the light-emitting layer 33 is disconnected on the first protruding structure 32.

Further, this first opening p1 may be formed in various ways, one way being that the first opening p1 may be formed on the light-emitting layer 33 by the patterning process, i.e., a portion of the light-emitting layer 33 on the top surface s1 of the first protruding structure 32 may be removed by an etching process in the patterning process, so as to form the first opening p1 in the light-emitting layer 33 on the top surface s1 of the first protruding structure 32.

In addition, as the position of the first opening p1 is on the top surface s1 of the first protruding structure 32, the height of the first opening p1 is greater than that of other positions of the edge region q2 of the display panel, which in turn can reduce the difficulty of forming the first opening p1 by the patterning process.

The display panel may further include a second encapsulation layer 39. The second encapsulation layer 39 is disposed on a side of the light-emitting layer 33 away from the substrate 31, the second encapsulation layer 39 has an encapsulation layer opening fk, and an orthographic projection of the encapsulation layer opening fk on the substrate 31 overlaps an orthographic projection of the first opening p1 on the substrate 31. The first encapsulation layer 34 is disposed on a side of the second encapsulation layer 39 away from the substrate 31, and the first encapsulation layer 34 covers the encapsulation layer opening fk. The second encapsulation layer 39 is an encapsulation layer for encapsulating the light-emitting units in the display panel, and can be used to protect the light-emitting units in the display panel from being damaged by the external environment.

In some embodiments, the light-emitting layer 33 includes a plurality of sub-light-emitting layers disposed in the display region. The display panel includes a plurality of light-emitting units. Each of the light-emitting units includes an electrode and the sub-light-emitting layers, the electrode being in contact with the sub-light-emitting layers to drive the sub-light-emitting layers to emit light. The second encapsulation layer 39 is disposed on a side of the plurality of light-emitting units away from the substrate 31 to encapsulate the plurality of light-emitting units.

It should be noted that the encapsulation layer opening fk in the second encapsulation layer 39 may be formed together with the first opening pl formed in the light-emitting layer 33 by the patterning process. Due to the patterning process, after the second encapsulation layer 39 of the light-emitting units in the display panel has been formed, the portion of the second encapsulation layer 39 and the light-emitting layer 33 disposed on the first protruding structure 32 are etched by the patterning process to achieve the structure for forming the first opening p1 on the light-emitting layer 33. For the encapsulation layer opening fk in the second encapsulation layer 39, the encapsulation layer opening fk can be covered by the first encapsulation layer 34, so as to avoid the moisture in the external environment from entering the display panel through the encapsulation layer opening fk. In addition, as the portion of the second encapsulation layer 39 disposed in the edge region can be adjusted by the etching process, the second encapsulation layer 39 can be formed without using a metal mask plate, such that the number of the metal mask plates used in the manufacturing process of the display panel can be reduced, thereby realizing the effect of reducing the manufacturing cost of the display panel.

The second encapsulation layer 39 may be a composite film layer including a plurality of film layers, exemplarily, the second encapsulation layer 39 may be a thin film encapsulation (TFE) layer. Exemplarily, the second encapsulation layer 39 may include a first inorganic encapsulation layer 391, an organic encapsulation layer 393, and a second inorganic layer 392 that are sequentially stacked in a direction away from the substrate 31. The first inorganic encapsulation layer 391 and the second inorganic encapsulation layer 392 may be formed by a chemical vapor deposition (CVD) process, and the organic encapsulation layer 393 may be formed by an inkjet printing (IJP) technique. The organic encapsulation layer 393 is fluid, and one function of the first protruding structure 32 is to limit the organic encapsulation layer 393 from flowing to the edge of the substrate 31. The first inorganic encapsulation layer 391 and the second inorganic layer 392 in the second encapsulation layer 39 may be covered on the first protruding structure 32, and the organic encapsulation layer 393 may not be covered on the first protruding structure 32. Alternatively, the thickness of one or more film layers in the second encapsulation layer 39 may be reduced, such that the encapsulation layer opening fk may be formed in the second encapsulation 39 by the patterning process. The thickness of the second inorganic layer may be reduced by 40% to 80% based on the conventional thickness of the first inorganic layer and the second inorganic layer.

The first encapsulation layer 34 may be another encapsulation layer in the display panel in addition to the second encapsulation layer 39. One first encapsulation layer 34 may include an inorganic buffer layer 341 and an inorganic interlayer dielectric layer 342.

Exemplarily, the display panel further includes a touch structure (not shown in FIG. 9). The touch structure is disposed on the side of the second encapsulation layer 39 away from the substrate 31, and the first encapsulation layer 34 is disposed on the side of the touch structure away from the substrate 31 to encapsulate the touch structure. That is, the first encapsulation layer 34 is a touch encapsulation layer for the touch structure, and the first encapsulation layer 34 can be used to cover the encapsulation layer openings fk in the second encapsulation layer 39, such that the influence of the encapsulation layer openings fk in the second encapsulation layer 39 caused by the formation of the first openings p1 in the light-emitting layer 33 by the patterning process can be eliminated without adding encapsulation layers.

In the display panel provided by the embodiments of the present disclosure, other film layers may also be included, such as a planarization layer b10 and an organic layer b11. The planarization layer b10 may be disposed on a side of the first encapsulation layer 34 away from the substrate 31, and the organic layer b11 may be disposed on a side of the planarization layer b10 away from the substrate 31.

Referring to FIG. 6 and FIG. 9, the plurality of film layers stacked in the first protruding structure 32 may include the metal layer m1 and the inorganic layer m2, wherein the inorganic layer m2 may include at least one of a first inorganic layer m21, a second inorganic layer m22, a third inorganic layer m23, a fourth inorganic layer m24, and a fifth inorganic layer m25. FIG. 9 shows a structure including the first inorganic layer m21, the second inorganic layer m22, the third inorganic layer m23, the fourth inorganic layer m24, and the fifth inorganic layer m25, which is not limited in the embodiments of the present disclosure.

The display panel may further include a first buffer layer b5, a first gate insulating layer (GI1) b6, a second gate insulating layer (GI2) b7, an interlayer dielectric (ILD) b8, and a passivation layer (PVX) b9 disposed sequentially on the substrate 31, of which a portion or all of the film layers may be inorganic layers.

In some embodiments, the first inorganic layer m21 is of the same layer structure as the first buffer layer b5, and thus the first inorganic layer m21 can be formed at the same time when the first buffer layer b5 is formed. The second inorganic layer m22 is of the same layer structure as the first gate insulating layer, and thus the second inorganic layer m22 can be formed at the same time when the first gate insulating layer is formed. The third inorganic layer m23 is of the same layer structure as the second gate insulating layer, and thus the third inorganic layer m23 can be formed at the same time when the second gate insulating layer is formed. The fourth inorganic layer m24 is of the same layer structure as the interlayer dielectric layer, and thus the third inorganic layer m24 can be formed at the same time when the interlayer dielectric layer is formed. The fifth inorganic layer m25 is of the same layer structure as the passivation layer, and thus the fifth inorganic layer m25 can be formed at the same time when the passivation layer is formed. In another structure, the first inorganic layer m21 may be the buffer layer, the second inorganic layer m22 may be of the same layer structure as the first gate insulating layer, the third inorganic layer m23 may be the second gate insulating layer, the fourth inorganic layer m24 may be the interlayer dielectric layer, and the fifth inorganic layer m25 may be the passivation layer.

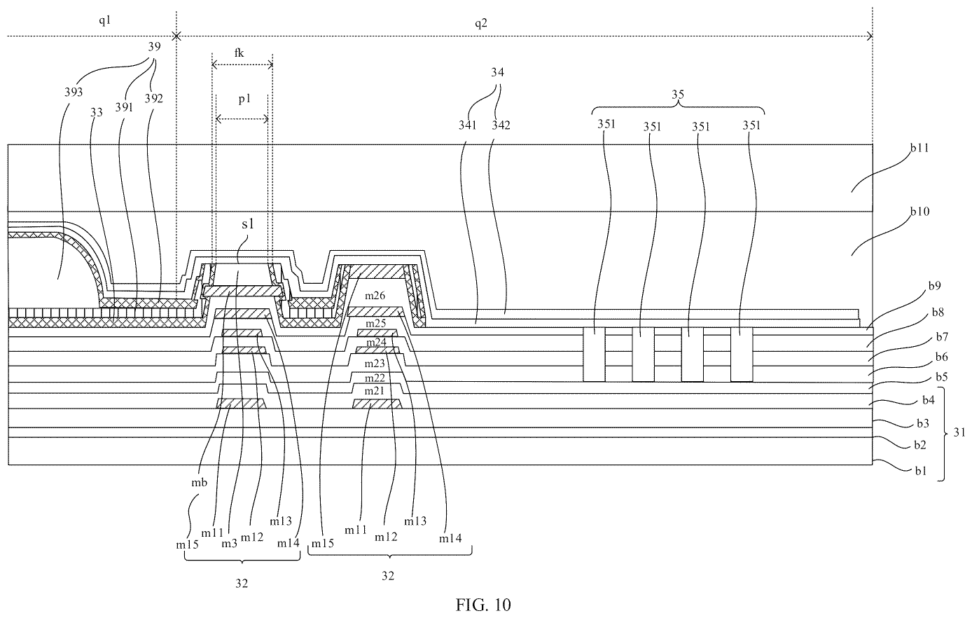

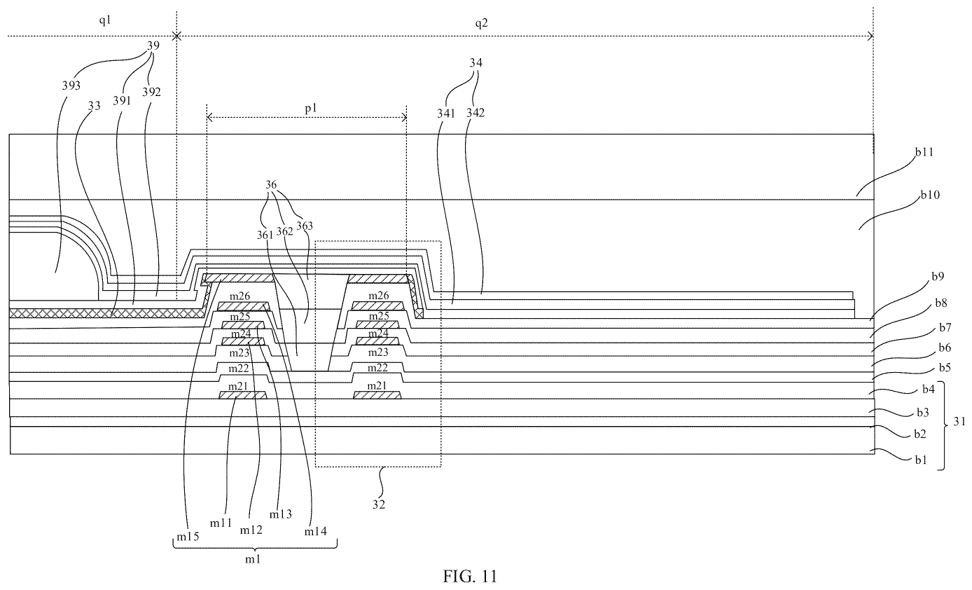

Also, referring to FIG. 10, FIG. 10 is another schematic cross-sectional view of FIG. 6 according to some embodiments of the present disclosure (the cross-sectional position may be at C-C or D-D), wherein the edge region may include two first protruding structures, one of the first protruding structures 32 may include a metal layer, the inorganic layer, and the organic layer m3, and the other first protruding structure 32 may include the metal layer and the inorganic layer.

Similar to the above embodiments, the metal layer may include at least one of the first metal layer m11, the second metal layer m12, the third metal layer m13, the fourth metal layer m14, the fifth metal layer m15, the sixth metal layer, and the seventh metal layer. The first metal layer m11 may be of the same layer structure as the metal shielding layer, and thus the first metal layer m11 may be formed at the same time when the metal shielding layer is formed. The second metal layer m12 may be of the same layer structure as the first gate metal pattern, and thus the second metal layer m12 may be formed at the same time when the first gate metal pattern is formed. The third metal layer m13 may be of the same layer structure as the second gate metal pattern, and thus the third metal layer m13 may be formed at the same time when the second gate metal pattern is formed. The fourth metal layer m14 may be of the same layer structure as the third gate metal pattern, and thus the fourth metal layer m14 may be formed at the same time when the third gate metal pattern is formed. The fifth metal layer m15 may be of the same layer structure as the first source-drain metal pattern, and thus the fifth metal layer m15 may be formed at the same time when the first source-drain metal pattern is formed. The sixth metal layer may be of the same layer structure as the second source-drain metal pattern, and thus the sixth metal layer can be formed at the same time when the second source-drain metal pattern is formed. The seventh metal layer is of the same layer structure as the third source-drain metal pattern, and thus the seventh metal layer can be formed at the same time when the third source-drain metal pattern is formed. In this way, the first protruding structure 32 can be formed without increasing the number of patterning processes.

The inorganic layer may include at least one of the first inorganic layer m21, the second inorganic layer m22, the third inorganic layer m23, the fourth inorganic layer m24, and the fifth inorganic layer m25. FIG. 10 shows a structure including the first inorganic layer m21, the second inorganic layer m22, the third inorganic layer m23, the fourth inorganic layer m24, and the fifth inorganic layer m25, which is not limited in the embodiments of the present disclosure. The display panel may also include a first buffer layer b5, a first gate insulating layer (GI1) b6, a second gate insulating layer (GI2) b7, an interlayer dielectric (ILD) b8, and a passivation layer (PVX) b9 disposed sequentially on the substrate 31, of which a portion or all of the film layers may be inorganic layers. Specific reference may be made to the display panel shown in FIG. 9 above, and the embodiments of the present disclosure are not repeated herein.

FIG. 11 is another schematic cross-sectional view of the display panel shown in FIG. 6 (the cross-sectional position may be at C-C or D-D). Referring to FIG. 6 and FIG. 11, the number of the first protruding structures 32 is at least two, and the at least two first protruding structures 32 include two adjacent first protruding structures 32. The two adjacent first protruding structures 32 may be arranged along a direction close to the display region, and the light-emitting layer 33 is disconnected on the two adjacent first protruding structures 32. The first opening p1 in the two first protruding structures 32 can be connected to a larger first opening p1, such that the first opening p1 formed by disconnecting the light-emitting layer 33 can be enlarged by a plurality of adjacent first protruding structures 32 to improve the blocking ability of the display panel against to the moisture in the external environment, thereby further increasing the service lifespan of the display panel.

The display panel further includes a filling structure 36, the filling structure 36 is disposed between and in contact with the two adjacent first protruding structures 32, and the filling structure 36 includes an organic material layer. The organic material layer has flexible and a bendable function, thus providing the filling structure 36 including the organic material layer between the two adjacent first protruding structures 32 can improve the bendable performance of the edge region and reduce the possibility of fracture of the edge region.

In some embodiments, the filling structure 36 may include one or more organic material layers, which may be of the same layer structure as the film layers including organic material in the display panel, e.g., a first planarization layer (PLN1), a second planarization layer (PLN2), and a pixel defining layer (PDL) may be included in the display panel. On this basis, the filling structure 36 may include at least one of a first organic material layer 361, a second organic material layer 362, and a third organic material layer 363. The first organic material layer 361 may be of the same layer structure as the first planarization layer, and thus the first organic material layer 361 may be formed at the same time when the first planarization layer is formed. The second organic material layer 362 may be of the same layer structure as the second planarization layer, and thus the second planarization layer 362 may be formed at the same time when the second planarization layer is formed. The third organic material layer 363 may be of the same layer structure as the pixel defining layer, and thus the third organic material layer 363 may be formed at the same time when the pixel defining layer is formed. In this way, the first protruding structure 32 can be formed without increasing the number of patterning processes.

In addition, the number of the organic material layers included in the filling structure 36 may be determined by the thickness of the filling structure 36. In some embodiments, the top of the filling structure 36 may be flush with the tops of the two first protruding structures 32 on both sides, which may be determined on a basis for determining the thickness of the filling structure 36 and the number of the organic material layers included in the filling structure 36.

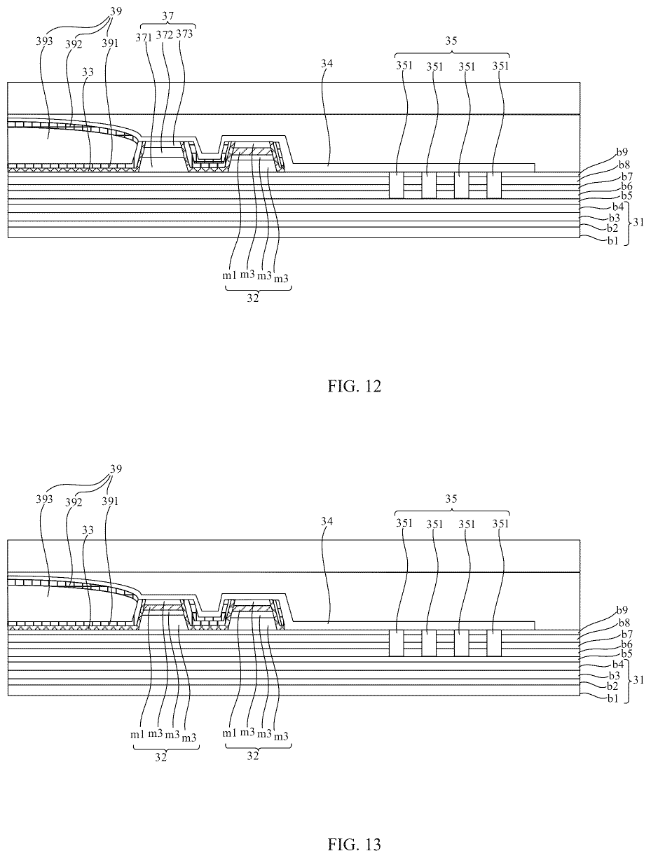

The above embodiments show a schematic structural diagram of a display panel in which an edge region includes a first protruding structure, but other protruding structures may be included in the edge region in the display panel provided by the embodiments of the present disclosure. Exemplarily, FIG. 12 is another schematic cross-sectional view of the display panel shown in FIG. 6 (the cross-sectional position may be at C-C or D-D). Referring to FIG. 6 and FIG. 12, the display panel further includes at least one second protruding structure 37. The second protruding structure 37 is disposed in the edge region q2, and the second protruding structure 37 includes at least one organic layer. The light-emitting layer 33 is disposed on the substrate 31 formed with the second protruding structure 37 and disconnected on the second protruding structure 37. The second protruding structure 37 may include at least one of a first layer 371, a second layer 372, and a third layer 373. The first layer 371 may be of the same layer structure as the first planarization layer, and thus the first layer 371 may be formed at the same time when the first planarization layer is formed. The second layer 372 may be of the same layer structure as the second planarization layer, and thus the second layer 372 may be formed at the same time when the second planarization layer 372 is formed. The third layer 373 may be of the same layer structure as the pixel defining layer, and thus the third layer 373 may be formed at the same time when the pixel defining layer is formed. In this way, the second protruding structure 37 may be formed without increasing the number of patterning processes.

Similar to the first protruding structure 37, the light-emitting layer 33 may be disconnected on the second protruding structure 37. The disconnection may mean that the light-emitting layer 33 is separated by the second protruding structure 37 into two portions disposed on both sides of the second protruding structure 37, which are spaced apart on the second protruding structure 37, and the spacing may separate the light-emitting layer 33 into a portion close to the display region q1 and another portion away from the display region q1. In this way, the blocking ability of the display panel for the moisture in the external environment is improved, thereby further increasing the service lifespan of the display panel.

The display panel provided in the embodiments of the present disclosure may include the first protruding structure 32 and the second protruding structure 37. As disclosed in some embodiments above, the first protruding structure 32 may have a variety of structures, and the first protruding structures of different structures may include different materials, but the second protruding structure 37 may be a protruding structure that includes only an organic material. As the organic material has a flexible and bendable function, and thus by providing the second protruding structure 37 only including the organic material in the edge region q2 of the display panel may enhance the flexibility of the edge region q2 and reduce the possibility of fracture of the edge region q2, thereby increasing the service lifespan of the display panel.

In the display panel provided by the embodiments of the present disclosure, at least one first protruding structure 32 and at least one second protruding structure 37 may be included. The first protruding structure 32 and the second protruding structure 37 may be arranged in a variety of forms in the edge region of the display panel. Exemplarily, in the case that the number of the first protruding structures 32 and the second protruding structures 37 are both one, the second protruding structure 37 may be disposed on a side of the first protruding structure 32 close to the display region q1. In this structure, the organic encapsulation layer 393 may be adjacent to the second protruding structure 37, and an orthographic projection of the organic encapsulation layer 393 on the substrate 31 may at least partially overlap an orthographic projection of the second protruding structure 37 on the substrate 31. In this way, the second protruding structure 37 can block the overflow of the organic encapsulation layer 393 having fluidity during the manufacturing process of the display panel.

In addition, the second protruding structure 37 may also be disposed on a side of the first protruding structure 32 away from the display region q1, and the first protruding structure 32 blocks the overflow of the organic encapsulation layer 393 having fluidity. In the case that the number of the first protruding structure 32 and the second protruding structure 37 is both two, the two first protruding structures 32 and the two second protruding structures 37 may be alternately arranged in the edge region of the display panel. In the case that the number of the first protruding structures 32 is one and the number of the second protruding structures 37 is two, the two second protruding structures 37 may be disposed on both sides of the first protruding structure 32.

Other film layer structures in FIG. 12 can be referred to other embodiments of the present disclosure and are not repeated herein.

FIG. 13 is another schematic cross-sectional view of the display panel shown in FIG. 6 (the cross-sectional position may be at C-C or D-D). Referring to FIG. 6 and FIG. 13, in the display panel shown in FIG. 13, at least two first protruding structures 32 are arranged in the edge region q2, wherein one of the protruding structures 32 may be adjacent to the organic encapsulation layer 393, and an orthographic projection of the organic encapsulation layer 393 on the substrate 31 may at least partially overlap an orthographic projection of the first protruding structure 32 on the substrate 31. With such a structure, the first protruding structure 32 can block the overflow of the organic encapsulation layer 393 having fluidity during the manufacturing process of the display panel.

Other film layer structures in FIG. 13 can be referred to other embodiments of the present disclosure and are not repeated herein.

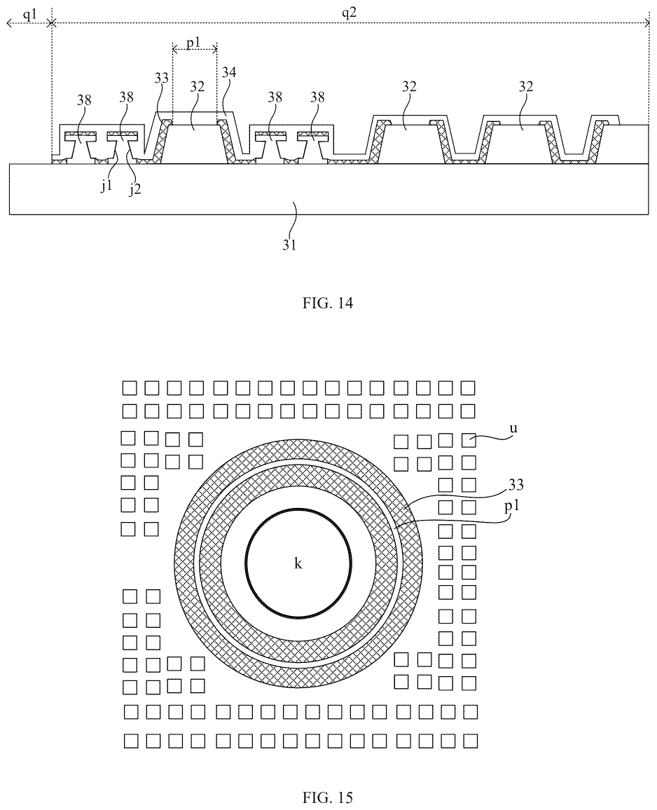

The above embodiments show some schematic structural diagrams that the edge region of the display panel includes the first protruding structure and the second protruding structure, and the display panel provided by the embodiments of the present disclosure may also include some other protruding structures. Exemplarily, FIG. 14 is another schematic cross-sectional view of the display panel shown in FIG. 6 (the cross-sectional position may be at C-C or D-D). Referring to FIG. 6 and FIG. 14, the display panel further includes at least one third protruding structure 38. The third protruding structure 38 is disposed in the edge region q2 on the substrate 31 and formed by the metal layer (e.g., one metal layer or a plurality of metal layers), a recessed structure is disposed in at least one of a first side surface j1 of the third protruding structure 38 close to the display region q1 and a second side surface j2 of the third protruding structure 38 away from the display region q1. Both side surfaces provided with the recessed structure which forms a structure similar to an I shape (the third protruding structure 38 of the structure may be formed by stacking three metal layers) is shown in FIG. 14, which is not limited in the embodiments of the present disclosure. The light-emitting layer 33 is disposed on the substrate 31 formed with the third protruding structure 38, and disconnected at the recessed structure of the third protruding structure 38. In this way, the moisture in the external environment can be prevented from intruding into the interior of the display panel through the light-emitting layer 33, thereby improving the blocking ability of the display panel for the moisture in the external environment, and further increasing the service lifespan of the display panel.

The display panel may also include a protruding structure including only the metal layer, and the third protruding structure 38 may be an isolation pillar. Compared to the first protruding structure 32 which includes a metal layer and other inorganic and organic layers, the third protruding structure 38 is formed only by the metal layer. As the metal layer has the characteristics of structural robustness and stability, the third protruding structure 38 can further enhance the robustness and stability of the protruding structure compared to the first protruding structure 32.

The number of third protruding structures 38 may be one or more. In the case that the number of third protruding structures is more, the plurality of third protruding structures 38 may be disposed on both sides of the first protruding structure 32 (the two sides may refer to one side close to the display region q1, and the other side away from the display region q1).

In addition, in some embodiments, the light-emitting layer 33 may be disconnected on the third protruding structure 38. The disconnection may mean that the light-emitting layer 33 is separated by the third protruding structure 38 into two portions disposed on both sides of the third protruding structure 38. The two portions are spaced on the third protruding structure 38, which may separate the light-emitting layer 33 into one portion close to the display region q1 and the other portion away from the display region q1. In this way, the blocking ability of the display panel to the moisture in the external environment is improved, thereby further increasing the service lifespan of the display panel.

In FIG. 14, the first protruding structure 32 and the second protruding structure may also be included. Some other structures, such as the first protruding structure 32 and the second protruding structure, may be referred to the above embodiments, and are not repeated herein.

It is to be noted that in the display panel provided by the embodiments of the present disclosure, the first opening p1 disposed in the top of the first protruding structure may be an opening around the edge region. The shape of the first opening pl may be different according to the edge region. Exemplarily, in the case that the edge region is the substrate edge region, the first opening p1 may be an opening around the display region; and in the case that the edge region is the opening-hole edge region, the first opening pl may be an opening around the opening hole in the substrate. Exemplarily, FIG. 15 is an enlarged schematic diagram of a partial region in the display panel shown in FIG. 6. For the purpose of clearly showing the first opening p1, some film layers above the light-emitting layer 33 are not shown in FIG. 15. In FIG. 15, u denotes a region occupied by the light-emitting units. As can be seen from FIG. 15, the first opening pl surrounds the opening hole k in the substrate 31 and forms in an annular shape, such that the opening hole k in the substrate can be surrounded in its entirety. In this way, the moisture in the external environment is prevented from entering into the display region q1 through the light-emitting layer 33 at the opening hole k, thereby further improving the blocking ability of the display panel for the moisture in the external environment, and increasing the lifespan of the display panel.

The disconnection structure on the light-emitting layer in the display panel provided in the embodiments of the present disclosure may also be formed in some other way. Exemplarily, a portion of the light-emitting layer disposed on the first protruding structure may be removed by a laser, such that the light-emitting layer may be disconnected on the first protruding structure.

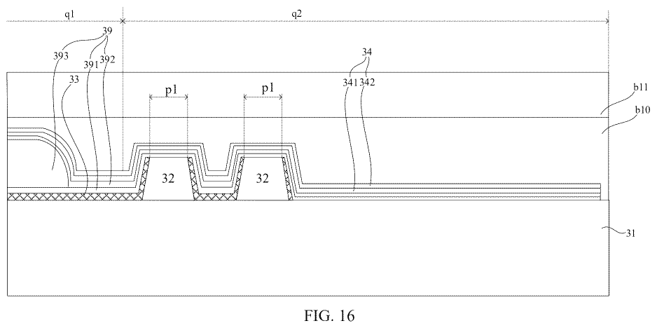

FIG. 16 is another schematic cross-sectional view of the display panel shown in FIG. 6 (the cross-sectional position may be at C-C or D-D). Referring to FIG. 6 and FIG. 16, the display panel further includes a second encapsulation layer. The second encapsulation layer 39 is disposed between the first encapsulation layer 34 and the light-emitting layer 33 and covers the first opening pl on the light-emitting layer. As the laser can pass through the second encapsulation layer 39, after the second encapsulation layer 39 is formed without forming the encapsulation layer opening in the second encapsulation layer 39, a portion of the light-emitting layer disposed on the first protruding structure 32 can be removed by a laser passing through the second encapsulation layer.

The second encapsulation layer 39 may be an encapsulation layer for encapsulating the light-emitting units in the display panel, and is used to protect the light-emitting units in the display panel from being damaged by the external environment.

The light-emitting layer 33 includes a plurality of sub-light-emitting layers disposed in the display region. The display panel includes a plurality of light-emitting units. Each of the light-emitting units includes an electrode and the sub-light-emitting layers, the electrode being in contact with the sub-light-emitting layers to drive the sub-light-emitting layers to emit light. The second encapsulation layer 39 is disposed on the side of the plurality of light-emitting units away from the substrate 31 to encapsulate the plurality of light-emitting units u. That is, the second encapsulation layer is an encapsulation layer for the light-emitting units.

In addition, the first encapsulation layer 34 is disposed on the side of the second encapsulation layer 39 away from the substrate 31, and the first encapsulation layer 34 may be another encapsulation layer in the display panel other than the second encapsulation layer 39. Exemplarily, the display panel further includes a touch structure, the touch structure is disposed on the side of the second encapsulation layer 39 away from the substrate 31, and the first encapsulation layer 34 is disposed on the side of the touch structure away from the substrate 31 to encapsulate the touch structure. That is, the first encapsulation layer 34 is a touch encapsulation layer for the touch structure.

The display panel in FIG. 16 may include the first protruding structure 32, the structure of which may refer to other embodiments and accompanying drawings of the present disclosure and is not repeated herein. In addition, the display panel may also include the second protruding structure and the third protruding structure, the structure of which may be referred to other embodiments and accompanying drawings of the present disclosure and are not repeated herein.

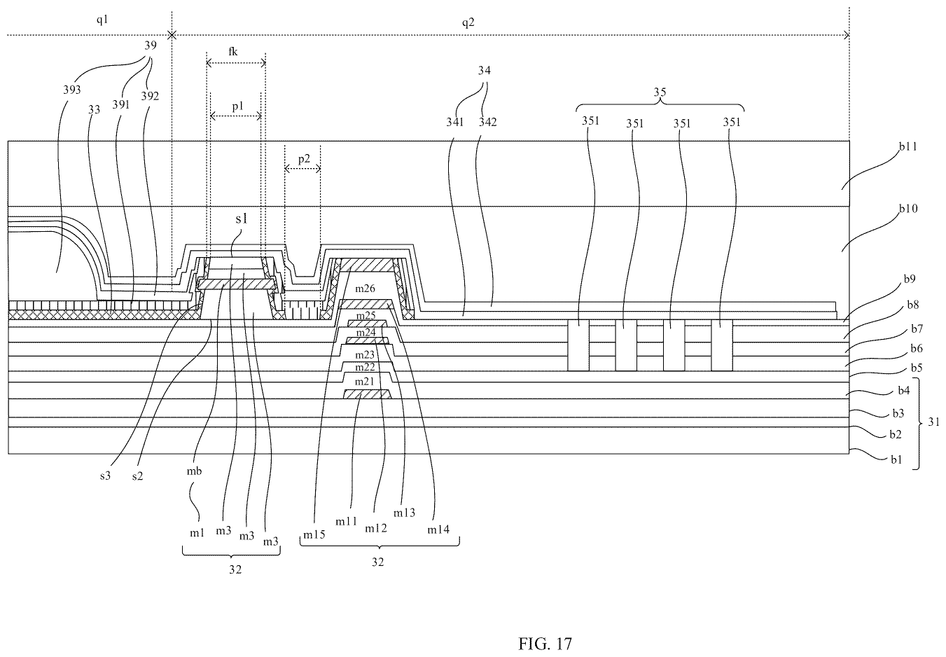

FIG. 17 is another schematic cross-sectional view of the display panel shown in FIG. 6 (the cross-sectional position may be at C-C or D-D). Referring to FIG. 6 and FIG. 17, the light-emitting layer 33 further includes a second opening p2, an orthographic projection of the second opening p2 on the substrate 31 is disposed between the orthographic projections of two adjacent first protruding structures 32 of at least two first protruding structures 32 on the substrate 31. That is, a disconnected structure may also be formed on the light-emitting layer 33 disposed on a region between the first protruding structures 32, thereby further improving the blocking ability of the display panel for the moisture in the external environment, and increasing the lifespan of the display panel.

The second opening p2 may be formed in a variety of ways. In some embodiments, the light-emitting layer 33 disposed on the region between the first protruding structures 32 may be etched by the patterning process to form the second opening p2. Alternatively, the second opening p2 may be formed by a laser process.

The contents of other film layers in FIG. 17 may refer to other accompanying drawings and embodiments of the present disclosure, and are not repeated herein.

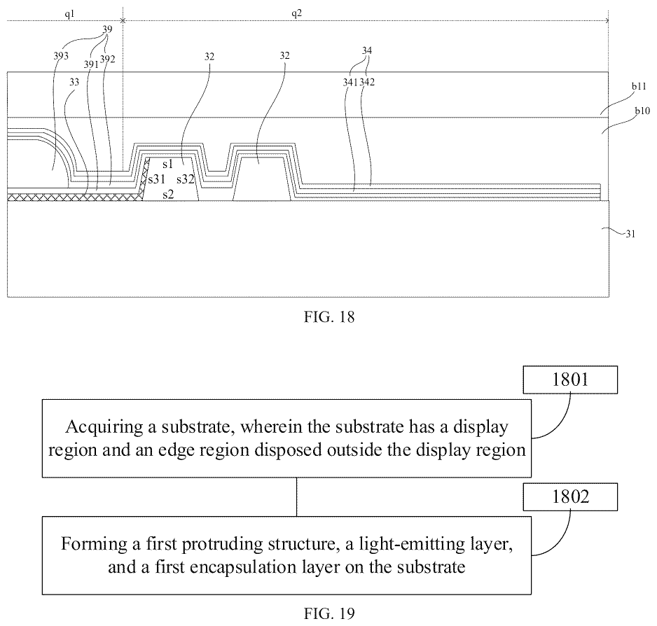

FIG. 18 is another schematic cross-sectional view of the display panel shown in FIG. 6 (the cross-sectional position may be at C-C or D-D). Referring to FIG. 6 and FIG. 18, the first protruding structure 32 is enclosed by a top surface s1, a bottom surface s2, and a side surface, the top surface s1 is disposed on a side of the bottom surface away from the substrate, and the side surface includes a first side surface s31 close to the display region q1 and a second side surface s32 away from the display region q1. The light-emitting layer 33 is disposed on the first side surface s31 and is not disposed on the top surface s1 and the second side s32. In this way, a distance between the edge of the light-emitting layer disposed on various edge regions of the substrate (e.g., the opening-hole edge region and the substrate edge region) and the various edges of the substrate (e.g., the edges of the opening hole of the substrate and the outer edges of the substrate) can be increased, thereby further improving the blocking ability of the display panel for the moisture in the external environment, and increasing the lifespan of the display panel.

The display panel in FIG. 18 may include the first protruding structure 32, the structure of which may refer to other accompanying drawings and embodiments of the present disclosure, and is not repeated herein. In addition, the display panel may also include the second protruding structure and the third protruding structure, the structure of which may refer to other accompanying drawings and embodiments of the present disclosure, and are not repeated herein.

In summary, the embodiments of the present disclosure provide a display panel including a substrate, a first protruding structure, a light-emitting layer, and an encapsulation layer. The first protruding structure is disposed in an edge region outside the display region, the light-emitting layer is disposed on the first protruding structure, and the light-emitting layer is disconnected on the protruding structure. In this way, the moisture in the external environment can be prevented from intruding into the display region of the display panel through the light-emitting layer, such that the risk of the display panel being damaged is reduced by the moisture in the external environment, thereby solving the problem that the poor stability of the display panel caused by the weakness of the display panel's ability to block the moisture in the external environment in the related art, and then achieving the effect of increasing the lifespan of the display panel.

FIG. 19 is a flowchart of a method for manufacturing a display panel according to some embodiments according to the present disclosure. The method may be used to manufacture the display panel provided by the above embodiments, including the following processes.

In S1801, a substrate is acquired, wherein the substrate has a display region and an edge region disposed outside the display region.

In S1802, a first protruding structure, a light-emitting layer, and a first encapsulation layer are formed on the substrate.

The first protruding structure is disposed in the edge region on the substrate, the first protruding structure includes a plurality of film layers that are stacked, the plurality of film layers including at least one metal layer. The light-emitting layer is disposed on a side of the first protruding structure away from the substrate, and disposed in the display region and the edge region, and the light-emitting layer is disconnected on the first protruding structure. The first encapsulation layer is disposed on a side of the light-emitting layer away from the substrate.

In summary, the embodiments of the present disclosure provide the method for manufacturing the display panel, the display panel manufactured by the method includes a substrate, a first protruding structure, a light-emitting layer, and an encapsulation layer. The first protruding structure is disposed in an edge region outside the display region, the light-emitting layer is disposed on the first protruding structure, and the light-emitting layer is disconnected on the protruding structure. In this way, the moisture in the external environment can be prevented from intruding into the display region of the display panel through the light-emitting layer, such that the risk of the display panel being damaged is reduced by the moisture in the external environment, thereby solving the problem that the poor stability of the display panel caused by the weakness of the display panel's ability to block the moisture in the external environment in the related art, and then achieving the effect of increasing the lifespan of the display panel.

In the method for manufacturing the display panel provided by the embodiments of the present disclosure, the light-emitting layer may be disconnected on the first protruding structure in a variety of ways. In one way, the above S1802 may include the following processes.
1) The first protruding structure is formed on the substrate.

The structure of the first protruding structure may be various, and reference may be made to some embodiments described above, which are not described herein.
2) The light-emitting layer is formed on the substrate formed with the first protruding structure.

The light-emitting layer may be formed by a process such as a vapor deposition process, the light-emitting layer may be disposed in the display region and the edge region on the substrate, and the light-emitting layer disposed in the display region may cooperate with some other structures to form light-emitting units to achieve a display function of the display panel.

The specific structure of the light-emitting layer can refer to FIG. 5 and the corresponding embodiments, which are not repeated herein.
3) A light-emitting layer opening is formed in the light-emitting layer by a laser process to disconnect the light-emitting layer on the first protruding structure.

An orthographic projection of the light-emitting layer opening on the substrate overlaps an orthographic projection of the first protruding structure on the substrate, and a portion of the light-emitting layer on the first protruding structure may be removed by a laser process to disconnect the light-emitting layer on the first protruding structure.
4) A second encapsulation layer is formed on the light-emitting layer.

The second encapsulation layer may be an encapsulation layer of the light-emitting units in the display panel, and subsequently a touch structure and an encapsulation layer of the touch structure may be formed on the second encapsulation layer. In this way, the light-emitting layer may be processed before the second encapsulation layer is formed, such that the light-emitting layer is disconnected on the first protruding structure.

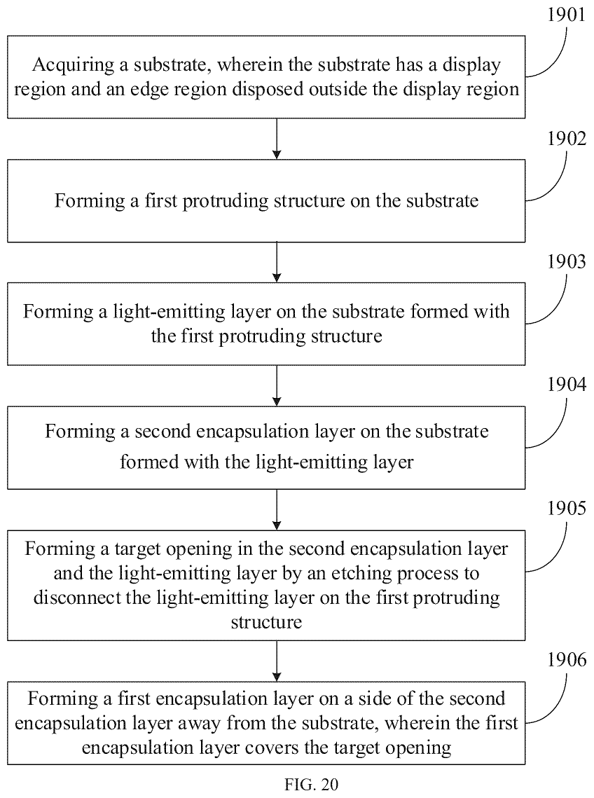

FIG. 20 is a flowchart of another method for manufacturing a display panel according to some embodiments of the present disclosure. The method is used to manufacture the display panel provided by the above embodiments, and includes the following processes.

In S1901, a substrate is acquired, wherein the substrate has a display region and an edge region disposed outside the display region.

The substrate may be manufactured by a backplane manufacturing process. Exemplarily, as shown in FIG. 9, the substrate 31 may include a first substrate layer b1, a second substrate layer b2, a third substrate layer b3, and a fourth substrate layer b4. The first substrate layer b1 and the third substrate layer b3 may be polyimide layers, and the second substrate layer b2 and the fourth substrate layer b4 may be inorganic buffer layers.

In S1902, a first protruding structure is formed on the substrate.

The specific structure of the first protruding structure can refer to some embodiments described above. Exemplarily, as shown in FIG. 9, the number of the first protruding structures 32 is at least two, and film layers in the at least two first protruding structures 32 include at least one of the three structures. The three structures include:
1) a metal layer and an inorganic layer;
2) a metal layer and an organic layer; and
3) a metal layer, an organic layer, and an inorganic layer.

In addition, in S1902, a second protruding structure and a third protruding structure may be formed, and the specific structures of the second protruding structure and the third protruding structure may refer to some embodiments described above, which are not repeated herein.

In S1903, a light-emitting layer is formed on the substrate formed with the first protruding structure.

The light-emitting layer may be formed by a process such as a vapor deposition process, the light-emitting layer may be disposed in a display region and an edge region on the substrate, and the light-emitting layer disposed in the display region may cooperate with some other structures to form light-emitting units to achieve a display function of the display panel.

The specific structure of the light-emitting layer can refer to FIG. 5 and the corresponding embodiments, which are not repeated herein.

In addition, when forming the light-emitting layer, the light-emitting layer can be formed in the display region and the edge region (e.g., a substrate edge region and an opening-hole edge region) without using an open mask. In this way, one mask plate can be reduced in the manufacturing process of the display panel, so as to reduce the manufacturing cost of the display panel.

In S1904, a second encapsulation layer is formed on the substrate formed with the light-emitting layer.

The second encapsulation layer may be an encapsulation layer for the light-emitting units in the display panel, and furthermore, an edge of the second encapsulation layer may cover an edge of the light-emitting layer in the edge region, thereby avoiding the intrusion of the moisture in the external environment into the interior of the display panel through the light-emitting layer.

The specific structure of the second encapsulation layer can refer to the above embodiments, which are not repeated herein.

In S1905, a target opening is formed in the second encapsulation layer and the light-emitting layer by an etching process to disconnect the light-emitting layer on the first protruding structure.

An orthographic projection of the target opening on the substrate overlaps an orthographic projection of the first protruding structure on the substrate. In this way, to avoid the etching process affecting some structures in the display panel, after the second encapsulation layer is formed, a portion of the second encapsulation layer and the light-emitting layer disposed on the top of the first protruding structure may be etched, such that the light-emitting layer is disconnected on the first protruding structure.

In S1906, a first encapsulation layer is formed on a side of the second encapsulation layer away from the substrate, wherein the first encapsulation layer covers the target opening.

An opening formed in the second encapsulation layer due to an etching process may be covered by the first encapsulation layer to avoid the moisture in the external environment entering the display panel through the opening. The first encapsulation layer may be an encapsulation layer for a touch structure in the display panel, such that the opening in the second encapsulation layer can be sealed without increasing the number of the encapsulation layers.

In summary, the embodiments of the present disclosure provide a method for manufacturing a display panel. The display panel manufactured by the method includes a substrate, a first protruding structure, a light-emitting layer, and an encapsulation layer. The first protruding structure is disposed in an edge region outside the display region. The light-emitting layer is disposed on the first protruding structure, and the light-emitting layer is disconnected on the protruding structure. In this way, the moisture in the external environment can be prevented from intruding into the display region of the display panel through the light-emitting layer, such that the risk of the display panel being damaged is reduced by the moisture in the external environment, thereby solving the problem that the poor stability of the display panel caused by the weakness of the display panel's ability to block the moisture in the external environment in the related art, and then achieving the effect of increasing the lifespan of the display panel.

The embodiments of the present disclosure also provided a display device. The display device includes a power supply assembly and the display panel provided in any one of the above embodiments. The power supply assembly is electrically connected to the display panel.

The display device may be a variety of devices with a display function, such as a laptop computer, a smartphone, a monitor, a television, and various smart wearable devices.

As the display device includes the display panel provided in the above embodiments, the display device may in turn have a similar effect, i.e., the service lifespan of the display device can be increased and the manufacturing cost can be reduced.

The term “at least one of A and B” in the present disclosure is merely a description of an association relationship of an associated object, and indicates that three relationships may exist, for example, at least one of A and B may be indicated as: the existence of A alone, the existence of both A and B, and the existence of B alone. Similarly, “at least one of A, B, and C” means that seven relationships may exist, which can be indicated as: the existence of A alone, the existence of B alone, the existence of C alone, the existence of both A and B, the existence of both A and C, the existence of both C and B, the existence of both A, B, and C. Similarly, “at least one of A, B, C and D” means that fifteen relationships may exist, which can be indicated as: the existence of A alone, the existence of B alone, the existence of C alone, the existence of D alone, the existence of both A and B, the existence of both A and C, the existence of both A and D, the existence of both C and B, the existence of both D and B, the existence of both C and D, the existence of all A, B, and C, the existence of all A, B, and D, the existence of all A, C, and D, the existence of all B, C and D, and the existence of all A, B, C and D.

It should be noted that in the accompanying drawings, sizes, and regions of the layers may be exaggerated for the sake of clarity of the illustrations. Moreover, it is understood that when an element or layer is referred to as being “on” another element or layer, it may be directly on the other element, or intermediate layers may exist. Also, it is to be understood that when the element or layer is referred to as being “under” another element or layer, it may be directly under the other element, or more than one intermediate layer or element may exist. It is also understood that when a layer or element is referred to as being “between” two layers or elements, it may be the only layer between the two layers or elements, or more than one intermediate layer or element may also exist. Similar reference marks throughout indicate similar elements.

In the present disclosure, the terms “first,” “second,” “third,” and “fourth” are used for descriptive purposes only, and are not to be understood as indicating or implying relative importance. The term “a plurality of” refers to two or more, unless expressly limited otherwise.

The foregoing are only optional embodiments of the present disclosure and are not intended to limit the present disclosure, and any modifications, equivalent substitutions, improvements, etc. made within the spirit and principles of this present disclosure shall be included in the scope of protection of the present disclosure.

1. A display panel, comprising:
a substrate, having a display region and an edge region disposed outside the display region;
a first protruding structure, disposed in the edge region on the substrate and comprising a plurality of film layers which are stacked, wherein the plurality of film layers comprise at least one metal layer;
a light-emitting layer, disposed on a side of the first protruding structure away from the substrate, disposed in the display region and the edge region, and disconnected on the first protruding structure; and
a first encapsulation layer, disposed on a side of the light-emitting layer away from the substrate.

2. The display panel according to claim 1, wherein the substrate has an opening hole, the edge region comprises at least one of an opening-hole edge region and a substrate edge region, wherein the opening-hole edge region is a region comprising an edge of the opening hole, and the substrate edge region is a region comprising an outer edge of the substrate.

3. The display panel according to claim 1, wherein the first protruding structure further comprises at least one of an organic layer and an inorganic layer.

4. The display panel according to claim 3, wherein a number of first protruding structures is at least two, film layers in the at least two first protruding structures comprising at least one of three structures, wherein the three structures comprise:
a metallic layer and an inorganic layer;
a metallic layer and an organic layer; and
a metallic layer, an organic layer, and an inorganic layer.

5. The display panel according to claim 4, further comprising at least one of a metal shielding layer, a first gate metal pattern, a second gate metal pattern, a third gate metal pattern, a first source-drain metal pattern, a second source-drain metal pattern, and a third source-drain metal pattern disposed on the substrate;
wherein the metal layer in the first protruding structure comprises at least one of a first metal layer, a second metal layer, a third metal layer, a fourth metal layer, a fifth metal layer, a sixth metal layer, and a seventh metal layer, wherein the first metal layer is of a same layer structure as the metal shielding layer, the second metal layer is of a same layer structure as the first gate metal pattern, the third metal layer is of a same layer structure as the second gate metal pattern, the fourth metal layer is of a same layer structure as the third gate metal pattern, the fifth metal layer is of a same layer structure as the first source-drain metal pattern, the sixth metal layer is of a same layer structure as the second source-drain metal pattern, and the seventh metal layer is of a same layer structure as the third source-drain metal pattern.

6. The display panel according to claim 3, wherein a number of first protruding structures is at least two, the at least two first protruding structures comprising two adjacent first protruding structures;
wherein the display panel further comprises a filling structure, wherein the filling structure is disposed between and in contact with the two adjacent first protruding structures, and the filling structure comprises an organic material layer.

7. The display panel according to claim 1, further comprising at least one second protruding structure, wherein the second protruding structure is disposed in the edge region and comprises at least one organic layer;
wherein the light-emitting layer is disposed on the substrate formed with the second protruding structure and is disconnected on the second protruding structure.

8. The display panel according to claim 1, further comprising at least one third protruding structure, wherein the third protruding structure is disposed in the edge region on the substrate and is formed by a metal layer, a recessed structure is disposed in at least one of a first side surface of the third protruding structure close to the display region and a second side surface of the third protruding structure away from the display region;
wherein the light-emitting layer is disposed on the substrate formed with the third protruding structure and is disconnected at the recessed structure of the third protruding structure.

9. The display panel according to claim 1, wherein the at least one metal layer comprises a target metal layer, wherein an edge of the target metal layer protrudes, in a direction parallel to the substrate, from the first protruding structure.

10. The display panel according to claim 2, further comprising a crack blocking structure, wherein the crack blocking structure is disposed in the edge region and on a side of the first protruding structure away from the display region.

11. The display panel according to claim 1, wherein the first protruding structure is enclosed by a top surface, a bottom surface, and a side surface, the top surface being disposed on a side of the bottom surface away from the substrate; and
the light-emitting layer comprises a first opening, the first opening being disposed on the top surface.

12. The display panel according to claim 11, further comprising a second encapsulation layer;
wherein the second encapsulation layer is disposed on a side of the light-emitting layer away from the substrate and has an encapsulation layer opening, wherein an orthographic projection of the encapsulation layer opening on the substrate overlaps an orthographic projection of the first opening on the substrate; and
the first encapsulation layer is disposed on a side of the second encapsulation layer away from the substrate and covers the encapsulation layer opening.

13. The display panel according to claim 11, further comprising a second encapsulation layer, wherein the second encapsulation layer is disposed between the first encapsulation layer and the light-emitting layer and covers the first opening in the light-emitting layer.

14. The display panel according to claim 12, wherein the light-emitting layer comprises a plurality of sub-light-emitting layers disposed in the display region;
the display panel comprises a plurality of light-emitting units, wherein each of the light-emitting units comprises an electrode and the sub-light-emitting layers, the electrode being in contact with the sub-light-emitting layers; and
the second encapsulation layer is disposed on a side of the plurality of light-emitting units away from the substrate to encapsulate the plurality of light-emitting units.

15. The display panel according to claim 12, further comprising a touch structure, wherein the touch structure is disposed on the side of the second encapsulation layer away from the substrate; and
the first encapsulation layer is disposed on a side of the touch structure away from the substrate to encapsulate the touch structure.

16. The display panel according to claim 1, wherein a number of first protruding structures is at least two; and
the light-emitting layer comprises a second opening, wherein an orthographic projection of the second opening on the substrate is disposed between orthographic projections of two adjacent first protruding structures in the at least two first protruding structures on the substrate.

17. The display panel according to claim 1, wherein the first protruding structure is enclosed by a top surface, a bottom surface, and a side surface, wherein the top surface is disposed on a side of the bottom surface away from the substrate, and the side surface comprises a first side surface close to the display region, and a second side surface away from the display region; and
the light-emitting layer is disposed on the first side surface, and is not disposed on the top surface and the second side surface.

18. The display panel according to claim 1, wherein the light-emitting layer comprises an electroluminescent material layer and a functional layer, wherein the functional layer comprises at least one of a hole injection layer, a hole transporting layer, an electron transporting layer, an electron injection layer, and a cathode layer.

19. A method for manufacturing a display panel, comprising:
acquiring a substrate, wherein the substrate has a display region and an edge region disposed outside the display region; and
forming a first protruding structure, a light-emitting layer, and a first encapsulation layer on the substrate, wherein the first protruding structure is disposed in the edge region on the substrate and comprises a plurality of film layers which are stacked, the plurality of film layers comprising at least one metal layer; the light-emitting layer is disposed on the substrate formed with the first protruding structure, disposed in the display region and the edge region, and disconnected on the first protruding structure; and the first encapsulation layer is disposed on a side of the light-emitting layer away from the substrate.

20. The method according to claim 19, wherein said forming the first protruding structure, the light-emitting layer, and the first encapsulation layer on the substrate comprises:
forming the first protruding structure on the substrate;
forming the light-emitting layer on the substrate formed with the first protruding structure;
forming a second encapsulation layer on the substrate formed with the light-emitting layer;
forming a target opening in the second encapsulation layer and the light-emitting layer by an etching process to disconnect the light-emitting layer on the first protruding structure, wherein an orthographic projection of the target opening on the substrate overlaps an orthographic projection of the first protruding structure on the substrate; and
forming the first encapsulation layer on a side of the second encapsulation layer away from the substrate, wherein the first encapsulation layer covers the target opening.
